(19) United States
(12) Patent Application Publication
(10) Pub. No.: US 2014/0333320 A1
(43) Pub. Date: Nov. 13, 2014

(54) CIRCUIT ARRANGEMENT FOR DETECTING A SHORT CIRCUIT IN A POWER SWITCH ARRANGEMENT

(71) Applicant: CONTINENTAL AUTOMOTIVE GmbH, Hannover (DE)

(72) Inventor: Andrea Barnetova, Regensburg (DE)

(21) Appl. No.: 14/365,687

(22) PCT Filed: Dec. 11, 2012
(86) PCT No.: PCT/EP2012/075039

§ 371 Date: Jun. 16, 2014

(30) Foreign Application Priority Data
Dec. 16, 2011 (DE) 10 2011 088 912.4

(51) Int. Cl. G01R 31/04; G01R 31/00

(52) U.S. Cl. CPC G01R 31/04; G01R 31/006
USPC 324/503

(57) ABSTRACT

A circuit arrangement detects a short circuit between first and second terminal connections of a power switch for energizing a load connected to the first and second terminal connections. A first power switch is located between a high potential of a supply voltage and the first terminal connection and a second power switch is located between the second terminal connection and a low potential of the supply voltage. A first current measuring device is located in the current path of the first power switch and a second current measuring device is located in the current path of the second power switch. A first comparator compares the measured values of the first current measuring device with a first, low threshold and a second, high threshold value, and a second comparator compares the measured values of the second current measuring device with a first, low threshold and a second, high threshold value.

In motor vehicles, there is a plethora of loads which need to be switched on and off. Examples of such loads are resistive loads such as headlights, indicator lights, reversing lights and brake lights, capacitive loads such as piezo actuators for injection valves, for example, inductive loads for instance solenoids for injection valves or such valves in fluid lines and the actuation of a wide variety of electromotive actuators for operating windscreen wipers, window lifters, the throttle valve or similar.

Since the power in a motor vehicle is usually supplied from the vehicle battery, which usually has a voltage of 12 volts in the case of modern passenger vehicles and a voltage of 24 volts in the case of goods vehicles, high currents must flow for the necessary powers. Said currents must be able to be guided through appropriately configured electronic switches, usually power transistors. For resistive loads, purely high-side or low-side switches are usually used, while half-bridges are used to actuate inductive loads, in the case of which the load is connected both to the positive connection of the supply voltage via a high-side switch and to the ground connection of the supply voltage via a low-side switch. In addition, in a known manner, the freewheeling diodes must be provided at suitable points. When it must be possible for inductive loads to be charged and discharged again, half-bridges in the form of series-connected power transistors are usually provided, the load with respect to ground being connected to the connection point of said power transistors.

In order to actuate electromotive drives, full-bridges—also called H bridges—are often used in order for it to be possible to operate the motor in both directions. In this connection, the two connections of the electromotive drive are connected on one side to the high potential of the supply voltage via a high-side switch and on the other side to the low potential of the supply voltage—usually the ground connection—via a low-side switch. The body diodes of the power transistors used are usually used as freewheeling diodes in this case.

The electronic switching elements embodied as power transistors are usually implemented in integrated circuits—often designed as ASICs—in relatively large numbers and can be connected to the abovementioned full-bridges or half-bridges by means of suitable wiring. In this case, suitable control circuits are provided in the integrated circuit, which control circuits are usually controlled externally by a microcontroller and can control the switching on and off of the connected loads.

However, in the case of all the circuit topologies mentioned, short circuits can occur across the switches, from the connections of the load with respect to battery voltage or ground potential, or across the load. In addition, line interruptions can also occur. All of said fault cases must be reliably detected and must be able to be indicated in order for it to be possible for suitable measures to be taken to rectify the fault.

DE 10 2008 018 244 B3 describes, using the example of a half-bridge with an inductive load which is connected on one side to the positive potential of the supply voltage via a high-side switch and to the ground potential via a low-side switch, the detection of short circuits across the switches and from the load connections with respect to the potentials of the supply voltage and, in addition, a line fracture in the connection lines of the load. However, the detection of a short circuit across the load is not disclosed but is problematic since said short circuit can only be differentiated from a short circuit with respect to the supply voltage or the ground potential with great effort.

It is therefore the object of the invention to be able to detect such a short circuit across the load in a simple manner.

The object is achieved by means of a circuit arrangement according to claim 1 and a method according to claim 3. Advantageous developments are specified in the dependent claims.

Accordingly, the object is achieved by means of a circuit arrangement for detecting a short circuit between a first and a second connection of a power switch arrangement for energizing a load which is connectable to the first and second connection, having a first power switch arranged between a high potential of a supply voltage and the first connection and having a second power switch arranged between the second connection and the low potential of the supply voltage. A first and, respectively, second current-measuring device are arranged in the current path of the first power switch and the current path of the second power switch. The circuit arrangement also has a first and a second comparator for comparing the measured values of the first and, respectively, second current-measuring device with in each case a first, low and a second, higher threshold value.

The object is also achieved by means of a method for detecting a short circuit in the case of a circuit arrangement designed in accordance with claim 1, in which a short circuit between the first and the second connection, that is to say across the load, is detected by the first or the second comparator indicating that the second high threshold value has been exceeded and the respective other comparator indicating that at least the first, low threshold value has been exceeded.

The circuit arrangement according to the invention is designed as a half-bridge; however, it can also advantageously be extended to a full-bridge, wherein, consequently, a third power switch is arranged between the high potential of the supply voltage and the second connection and a fourth power switch is arranged between the first connection and the low potential of the supply voltage. Advantageously, both the third and the fourth power switch are in each case provided with a third and, respectively, fourth current-measuring device and a third and, respectively, fourth comparator for comparing the measured values of the current-measuring devices with a first, low and a second, higher threshold value. As a result, for example, an electromotive drive can be operated not only in one direction but in the other direction, too, wherein the short circuit across the load, i.e. between the first and the second connection, can be determined during operation in both operating modes when the higher threshold value has been exceeded in the current path of one of the active power switches and at least the low threshold value has been exceeded in the current path of the respective other power switch.

In this case, the low threshold value is advantageously a threshold value for a limit current which is a maximum permissible current for the circuit arrangement during normal operation. The second, higher threshold value is a threshold value which indicates an over current, that is to say a current which has attained an impermissibly high value and consequently suggests a short circuit.

In principle, the same current flows through the two active power switches and via the load or, in the event of a short circuit across the load, via the short-circuit connection, with the result that, in the event of a short circuit, both comparators should indicate the fact that the higher threshold value has been exceeded. However, the comparators and the reference current or voltage sources which form the threshold values are not made with high precision owing to the costs connected therewith, or can have variations. It is therefore possible that one comparator already indicates that the higher threshold value has been exceeded while the other comparator only indicates that the low threshold value, that is to say the limit current, has been exceeded. However, this is sufficient for detecting a short circuit across the load.

By contrast, it is not sufficient for an over current to be indicated in only one of the active current paths since this could also be in response to a short circuit of the respective connection with respect to the high or low supply potential. The possible fault cases are illustrated in the following table:

| | LSx | LSx | HSx | HSx |
|---|---|---|---|---|
| Fault cases | Ithreshold1 | Ithreshold2 | Ithreshold1 | Ithreshold2 |
| Short | X | X | X | |
| circuit | | | | |
| across the | | | | |
| load (1) | | | | |
| Short | X | | X | X |
| circuit | | | | |
| across the | | | | |
| load (2) | | | | |
| Short | X | X | X | X |
| circuit | | | | |
| across the | | | | |
| load (3) | | | | |
| Short | | | X | X |
| circuit with | | | | |
| respect to | | | | |
| GND at the | | | | |
| output OUTx | | | | |
| Short | X | X | | |
| circuit with | | | | |
| respect to | | | | |
| Vbat at the | | | | |
| output OUTx | | | | |

The invention will be described in more detail below on the basis of an exemplary embodiment with the aid of a figure, in which:

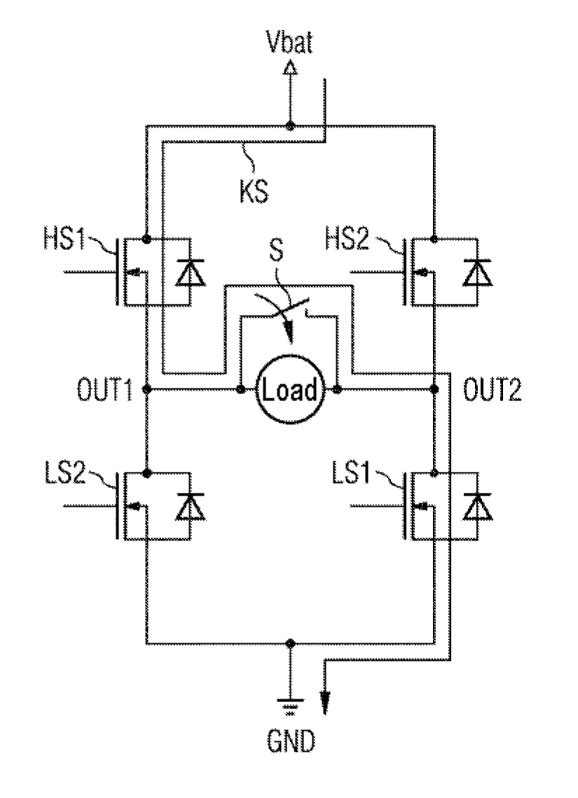

FIG. 1 shows a basic schematic diagram of a full-bridge with indicated short circuit across a connected load.

In the full-bridge power switch arrangement of FIG. 1, a first power switch HS1 is connected between the positive potential of the supply voltage Vbat and a first connection OUT1. A second power switch LS1 is arranged between a second connection OUT2 and the low potential of the supply voltage—in this case, the ground connection GND. A consumer Load is arranged between the first and second connection OUT1, OUT2, it being possible for said consumer to be a resistive, capacitive and inductive consumer. A connection path with a switch is shown above the consumer Load, which connection path is intended to symbolize a short circuit when the switch is closed. A continuous current path KS symbolizes a short-circuit current.

The power switches HS1, LS1 are embodied as n-channel MOSFETs in the illustrated example of FIG. 1 and have an intrinsic diode—often termed body diode.

This half of the full-bridge circuit illustrated in FIG. 1 would already be sufficient to supply the consumer Load with power from the supply source Vbat whilst the two power switches HS1, LS1 are closed. For this purpose, they would be actuated by means of a suitable control circuit—not shown—which itself can be actuated by means of a microprocessor—likewise not shown.

In order to form a full-bridge circuit, a third power switch HS2 is arranged between the positive supply voltage connection Vbat and the second connection OUT2, and a fourth power switch LS2 is arranged between the first connection OUT1 and the low supply voltage connection GND in FIG. 1. These power switches are also illustrated as n-channel MOSFETs with intrinsic diodes in the illustrated example.

Said intrinsic diodes are used as freewheeling diodes during operation of an inductive consumer when the current is disconnected.

In order to monitor the full-bridge circuit of FIG. 1, the current is detected in the respective branches of the circuit. For this purpose, current-measuring devices—not shown—are provided, said current-measuring devices being obvious to a person skilled in the art. Thus, for example, shunt resistors can be used, wherein the voltage dropping across said shunt resistors is a measure for the current in the respective current branches. Alternatively, current mirrors can also be used, the output current of which is a measure for the current flowing through the bridge-circuit branch.

The output signals of known current-measuring devices such as these are guided to comparators in a likewise known manner, which comparators compare said measured signals, which can be both currents and voltages that are representative of the flowing currents, with threshold values. For the circuit arrangement according to the invention, a first lower threshold value is provided and a second higher threshold value is provided, wherein the first, low threshold value is a limit current which represents a maximum permissible current for the circuit arrangement. The second, higher threshold value is an over current threshold value which represents an impermissibly high current at which the circuit would already be overloaded.

If a short circuit were present across the consumer Load, an impermissibly high current would flow, with the result that in each case the first, low threshold value would be detected by both current-measuring devices arranged in the branches through which the current flows and the connected comparator would correspondingly output a signal. Owing to tolerances, in each case one of the comparators would also indicate a current which exceeds the second, higher threshold value, with the result that an impermissible over current is indicated. In most cases, however, both comparators will indicate said impermissible over current.

In order to indicate a short circuit across the consumer Load, it is now only necessary in the manner according to the invention for one of the comparators assigned to the active current branches to indicate an over current and the respective other one to indicate at least that the limit current, that is to say the first, low threshold, has been exceeded. Preferably, it is determined in this case whether the over current occurs at least during a predefined time and therefore whether the current is above the second threshold value during this predefined time. This time is often referred to as filter time. This is necessary since only the indication of an over current in one of the circuit branches could likewise be a short circuit of the respective assigned connection OUT1 or OUT2 with respect to the high or low potential of the supply voltage Vbat, GND. Thus, for example, detection of an over current in the circuit branch containing the first power switch HS1 could be caused both by a short circuit across the consumer Load and by a short circuit of the first output OUT1 with respect to ground GND. If, however, that of the second power switch LS1 also indicates that at least the limit current threshold has been exceeded, then a short circuit is unambiguously present across the consumer Load since, in the event of a short circuit of the first connection OUT1 with respect to the ground connection GND, no correspondingly high current could flow through the second power switch LS1.

1-6. (canceled)

7. A circuit configuration for detecting a short circuit between a first connection and a second connection of a power switch configuration for energizing a load connected to the first and second connections, the circuit configuration comprising:
a first power switch disposed between a high potential of a supply voltage and the first connection;
a second power switch disposed between the second connection and a low potential of the supply voltage;
a first current-measuring device disposed in a current path of said first power switch;
a second current-measuring device disposed in a current path of said second power switch;
a first comparator for comparing measured values of said first current-measuring device with a first, low and a second, higher threshold value; and
a second comparator for comparing measured values of said second current-measuring device with a first, low and a second, higher threshold value.

8. The circuit configuration according to claim 7, further comprising:
a third power switch disposed between the high potential of the supply voltage and the second connection;
a fourth power switch disposed between the first connection and the low potential of the supply voltage;
a third current-measuring device disposed in a current path of said third power switch;
a fourth current-measuring device disposed in a current path of said fourth power switch;
a third comparator for comparing measured values of said third current-measuring device with a first, low and a second, higher threshold value; and
a fourth comparator for comparing measured values of said fourth current-measuring device with a first, low and a second, higher threshold value.

9. A method for detecting a short circuit between a first connection and a second connection of a power switch configuration for energizing a load connected to the first and second connections, wherein the power switch configuration having a first power switch disposed between a high potential of a supply voltage and the first connection, a second power switch disposed between the second connection and a low potential of the supply voltage, a first current-measuring device disposed in a current path of the first power switch, a second current-measuring device disposed in a current path of the second power switch, a first comparator for comparing measured values of the first current-measuring device with a first, low and a second, higher threshold value, and a second comparator for comparing measured values of the second current-measuring device with a first, low and a second, higher threshold value, which comprises the step of:
detecting a short circuit between the first connection and the second connection when the first or the second comparator indicates that the second high threshold value has been exceeded and the respective other comparator indicates that at least the first, low threshold value has been exceeded.

10. The method according to claim 9, wherein the power switch configuration further having a third power switch disposed between the high potential of the supply voltage and the second connection, a fourth power switch disposed between the first connection and the low potential of the supply voltage, a third current-measuring device disposed in a current path of the third power switch, a fourth current-measuring device disposed in a current path of the fourth power switch, a third comparator for comparing measured values of the third current-measuring device with a first, low and a second, higher threshold value, and a fourth comparator for comparing the measured values of the fourth current-measuring device with a first, low and a second, higher threshold value, the method further comprises:
detecting a short circuit between the first connection and the second connection when the third or the fourth comparator indicates that the second high threshold value has been exceeded and the respective other comparator indicates that at least the first, low threshold value has been exceeded.

11. The method according to claim 10, wherein the first, low threshold value is a threshold value for a limit current which is a maximum permissible current for the power switch configuration, and the second, higher threshold value is a threshold value for an over-current which is an impermissibly high current.

12. The method according to claim 11, which further comprises detecting the over-current when the current is above the second threshold value for a predefined time.
